(19) United States
(12) Patent Application Publication
(10) Pub. No.: US 2008/0079011 A1
(43) Pub. Date: Apr. 3, 2008

(54) ELECTROPHORETIC DISPLAY DEVICE AND METHOD OF FABRICATING THE SAME

(75) Inventors: Keun-Kyu SONG, Yongin-si (KR); Bo-Sung KIM, Seoul (KR); Seung-Hwan CHO, Hwaseong-si (KR)

Correspondence Address: MACPHERSON KWOK CHEN & HEID LLP, 2033 GATEWAY PLACE, SUITE 400, SAN JOSE, CA, 95110, US

(73) Assignee: Samsung Electronics Co., Ltd.

(21) Appl. No.: 11/866,341

(22) Filed: Oct. 2, 2007

(30) Foreign Application Priority Data
Oct. 3, 2006 (KR) 2006-097465

(51) Int. Cl. H01L 33/00; H01L 21/336

(52) U.S. Cl. 257/89; 438/35; 257/E33.001; 257/E21.409

(57) ABSTRACT

A display substrate includes a thin film transistor and a pixel electrode. The thin film transistor includes source and drain electrodes, an active layer covering the source and drain electrodes, and a gate electrode formed on the active layer. The pixel electrode includes the same material as that of the gate electrode, and is formed in the process of forming the gate electrode to reduce the number of process steps and the number of masks.

### CROSS-REFERENCE TO RELATED APPLICATION

This application relies for priorities upon Korean Patent Application No. 2006-0097465 filed on Oct. 3, 2006, the contents of which are herein incorporated by reference in their entirety.

### BACKGROUND OF THE INVENTION

1. Field of the Invention

The present invention relates to an Electrophoretic Display (EPD) and a method of fabricating the same.

2. Description of the Related Art

Unlike the liquid crystal display (LCD) which requires a backlight assembly, an electrophoretic display employs charged pigment particles that are moved by an applied electric field so that a separate light source is not necessary. Accordingly, an EPD is thinner and lighter than a LCD.

An EPD includes an array substrate, an opposite substrate facing the array substrate, and a pigment particle layer interposed between the array substrate and the opposite substrate. Pigment particles move toward the array substrate or the opposite substrate due to the electric field formed between the array substrate and the opposite substrate. The array substrate includes a gate line, a data line, a thin film transistor electrically connected to the gate line and the data line, a gate insulating layer, a passivation layer, and an organic insulating layer. As described above, since the array substrate includes a plurality of thin film layers, much time is required to pattern each thin film layer. Further, since about six masks are required to pattern the thin film layers, manufacturing cost is high.

### SUMMARY OF THE INVENTION

In one aspect of the present invention, a display substrate includes a base substrate, a thin film transistor, and a pixel electrode. Pixel areas representing an image are defined on the base substrate. The thin film transistor is formed in the pixel areas and switches the pixel voltage corresponding to an image. The thin film transistor includes a source electrode, a drain electrode, an active layer, and a gate electrode. The source electrode is formed on the base substrate, the drain electrode is formed on the same layer as the source electrode and is electrically connected to the pixel electrode, and the active layer covers the source electrode and the drain electrode. The gate electrode is formed on the active layer in the process of forming the pixel electrode. The gate electrode includes the same material as that of the pixel electrode. The pixel electrode is formed in the pixel areas and is electrically connected to the thin film transistor to output the pixel voltage.

In one aspect of the present invention, an EPD includes first and second display substrates, and a color layer interposed between the first display substrate and the second display substrate which represents an image by using polarized pigment particles.

In one aspect of the present invention, a method of fabricating a display substrate comprises forming a source electrode and a drain electrode in pixel areas of a base substrate, covering the source electrode and the drain electrode with an active layer, forming substantially simultaneously a gate electrode together with a pixel electrode on the active layer and electrically connecting the pixel electrode to the drain electrode.

According to the above, the gate electrode is formed by using the same material as that of a pixel electrode. Accordingly, the number of process steps and the number of masks are reduced, so that the productivity is improved and the manufacturing cost is saved.

### BRIEF DESCRIPTION OF THE DRAWINGS

The above and other advantages of the present invention will become readily apparent by reference to the following detailed description when considered in conjunction with the accompanying drawings, in which:

FIG. 1 is a plan view illustrating an exemplary embodiment of a display apparatus according to the present invention;

FIG. 2 is a sectional view taken along a line I-I′ shown in FIG. 1;

FIG. 3 is a sectional view taken along a line II-II′ shown in FIG. 1;

FIGS. 4A to 4F are sectional views illustrating a fabricating method of the display apparatus shown in FIG. 1;

FIG. 5 is a plan view illustrating another exemplary embodiment of a display apparatus according to the present invention;

FIG. 6 is a sectional view taken along a line III-III′ shown in FIG. 5;

FIGS. 7A to 7C are sectional views illustrating a fabricating method of the display apparatus shown in FIG. 6;

FIG. 8 is a plan view illustrating an exemplary embodiment of an EPD according to the present invention;

FIG. 9 is a sectional view taken along a line VI-VI′ shown in FIG. 8;

FIG. 10 is a sectional view taken along a line V-V′ shown in FIG. 8; and

FIG. 11 is a sectional view illustrating another exemplary embodiment of an EPD according to the present invention.

### DESCRIPTION OF THE EMBODIMENTS

Hereinafter, the present invention will be explained in detail with reference to the accompanying drawings. In the drawings, the thickness of layers, films, and regions are exaggerated for clarity. Like numerals refer to like elements throughout. It will be understood that when an element such as a layer, film, region, or substrate is referred to as being “on” another element, it can be directly on the other element or intervening elements may also be present.

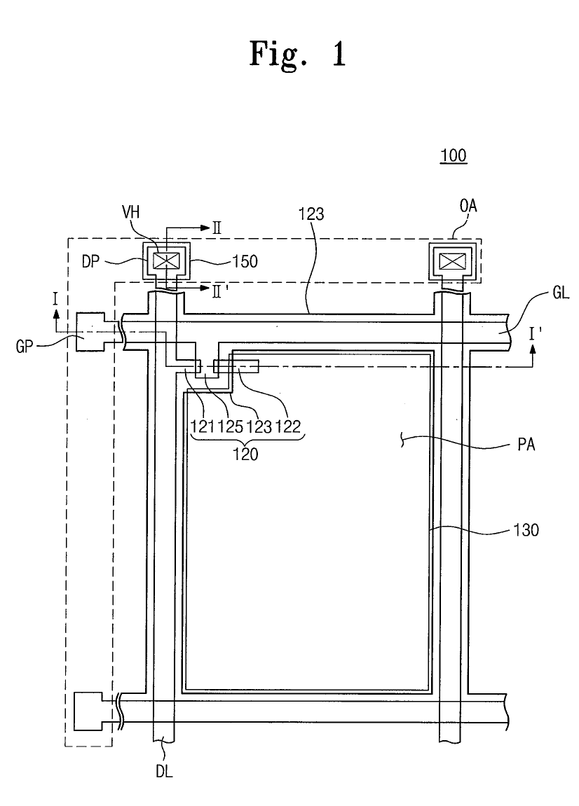

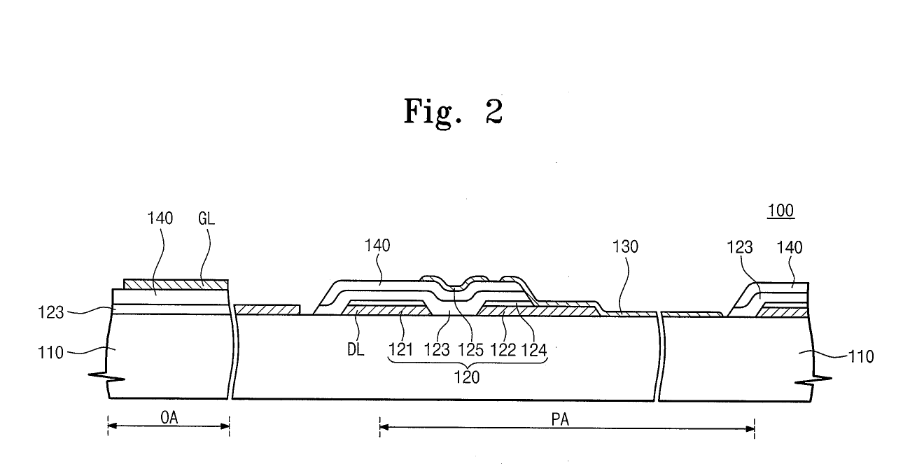

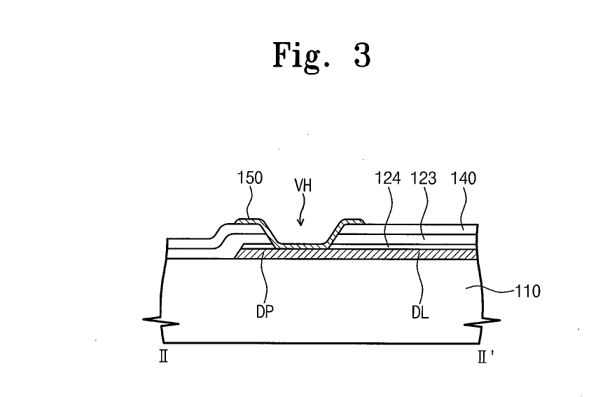

FIG. 1 is a plan view illustrating an exemplary embodiment of a display apparatus according to the present invention, FIG. 2 is a sectional view taken along a line I-I′ shown in FIG. 1, and FIG. 3 is a sectional view taken along a line 11-II′ shown in FIG. 1.

Referring to FIGS. 1 and 2, a display substrate 100 includes a first base substrate 110, a data line DL, a gate line GL, a thin film transistor 120, and a pixel electrode 130.

The first base substrate 110 includes a light permeable material, and a plurality of pixel areas PA representing an image and a peripheral area OA surrounding the pixel areas PA.

Referring to FIGS. 1 and 3, the data line DL is formed on the upper surface of the first base substrate 110, includes an opaque metallic material such as aluminum, aluminum alloy, molybdenum and chromium, and transmits data signals corresponding to the images. A data pad DP receiving the data signals from an outside is formed at one end portion of the data line DL. The data pad DP is formed in the peripheral area OA, and is electrically connected to an external apparatus (not shown) providing the data signals.

Referring to FIGS. 1 and 2, the gate line GL is formed on the upper portion of the first base substrate 110, and is insulated from the data line DL while crossing the data line DL. The gate line GL defines the pixel areas PA in combination with the data line DL, includes an opaque metallic material such as aluminum, aluminum alloy, molybdenum and chromium, and transmits gate signals corresponding to the images. A gate pad GP receiving the gate signals from an outside is formed at one end portion of the gate line GL. The gate pad GP is formed in the peripheral area OA, and is electrically connected to external apparatus (not shown) providing the gate signals.

The thin film transistor 120 and the pixel electrode 130 are formed in each pixel area PA of the first base substrate 110. The thin film transistor 120 includes a source electrode 121, a drain electrode 122, an active layer 123, an ohmic contact layer 124 and a gate electrode 125.

The source electrode 121 branches from the data line DL. The drain electrode 122 and the source electrode 121 are formed on the same layer such that the drain electrode 122 is spaced apart from the source electrode 121 and is electrically connected to the pixel electrode 130.

The active layer 123 covers the data line DL, the source electrode 121 and the drain electrode 122, and a portion of the active layer 123, on which the gate line GL is formed in the peripheral area OA, is formed on the upper surface of the first base substrate 110. The active layer 123 is partially removed at the upper portion of the drain electrode 122 to expose the drain electrode 122. In the present exemplary embodiment, the active layer 123 covers a first end portion of the drain electrode 122, and is removed at the opposite end portion of the drain electrode 122. The ohmic contact layer 124 is formed at a lower portion of the active layer 123, so that the ohmic contact layer 124 is located on the data line DL, the source electrode 121 and the drain electrode 122.

The gate electrode 125 branches from the gate line GL, and is formed on the active layer 123. The gate line GL is formed together with the gate electrode 125, so that the gate line GL is located on the active layer 123. In plan view, the gate electrode 125 is formed between the source electrode 121 and the drain electrode 122 so that the gate electrode 125 partially overlaps the source electrode 121 and the drain electrode 122. The gate electrode 125 includes an opaque metallic material such as aluminum, aluminum alloy, molybdenum and chromium.

The pixel electrode 130 is in contact with an end portion of the drain electrode 122, and outputs pixel voltage corresponding to the images. The pixel electrode 130 is formed in an area except where the gate electrode 125 is formed, and is spaced apart from the data line DL and the gate line GL. The pixel electrode 130 includes the same metallic material as gate electrode 125, i.e. an opaque metallic material, and is formed in the process of forming the gate electrode 125. Accordingly, the number of process steps and the number of masks for the display substrate 100 may be reduced, so that productivity is improved and manufacturing cost is saved.

The display substrate 100 further includes a first insulating layer 140 insulating gate line GL and gate electrode 125 from the conductive layer formed at the lower portion of gate line GL and gate electrode 125. The first insulating layer 140 is formed on the active layer 123 to correspond to the active layer 123, and includes silicon nitride-based material SiNx or silicon oxide-based material SiOx. The gate line GL and the gate electrode 125 are formed on the first insulating layer 140.

Referring to FIGS. 1 and 3, the active layer 123, the ohmic contact layer 124 and the first insulating layer 140 are removed at the upper portion of the data pad DP to form a via hole VH therethrough, and the data pad DP is exposed through the via hole VH.

The display substrate 100 further includes an electrode pad 150 electrically interconnecting the data pad DP and external apparatus that provides the data signals. The electrode pad 150 is formed on the first insulating layer 140 to correspond to the data pad DP, and is electrically connected to the data pad DP through the via hole VH. The electrode pad 150 includes the same material as that of the gate electrode 125, and is obtained in the process of forming the gate electrode 125.

As shown in FIG. 2, the gate line GL is formed on the first insulating layer 140. Accordingly, the display apparatus 100 does not need to have a separate electrode pad electrically interconnecting the gate pad GP with external apparatus that provides the gate signals.

Hereinafter, the process of fabricating the display substrate 100 will be described in detail with reference to the accompanying drawings.

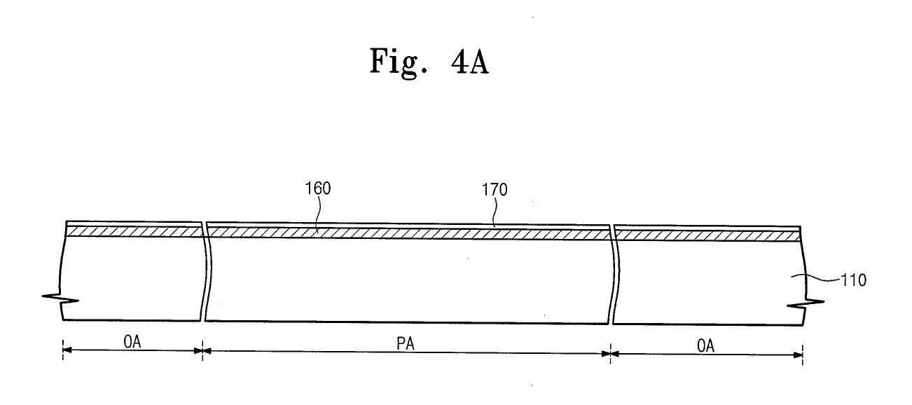

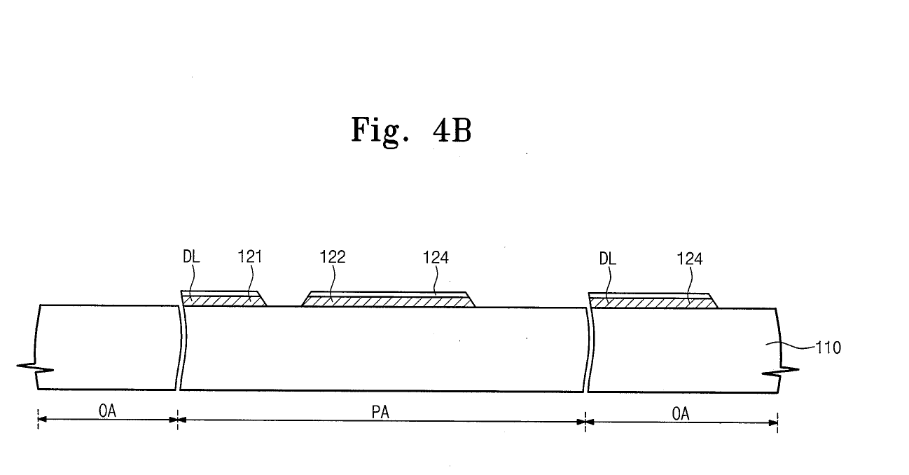

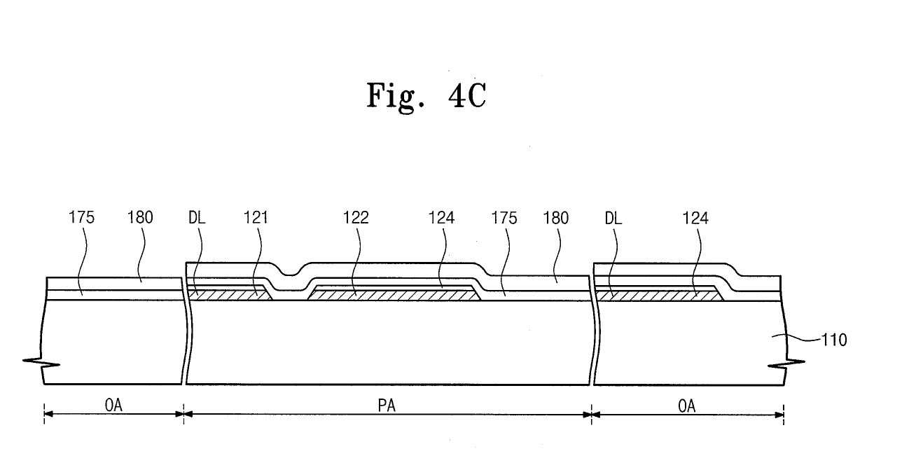

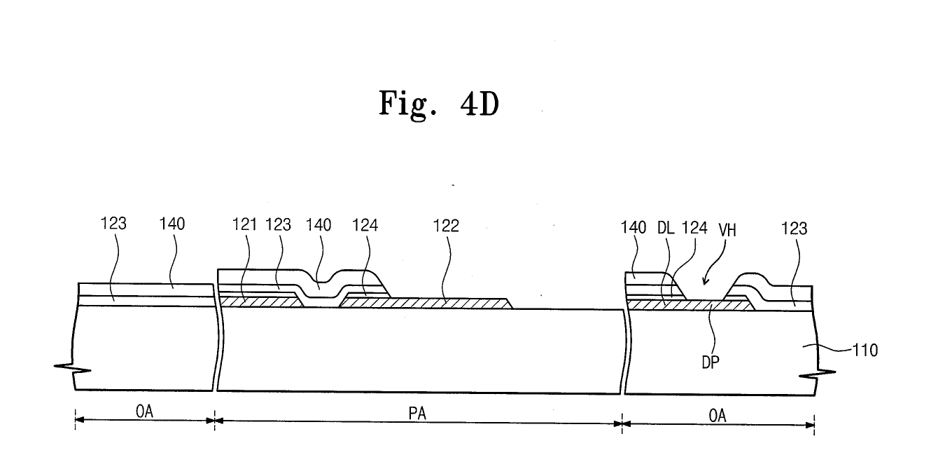

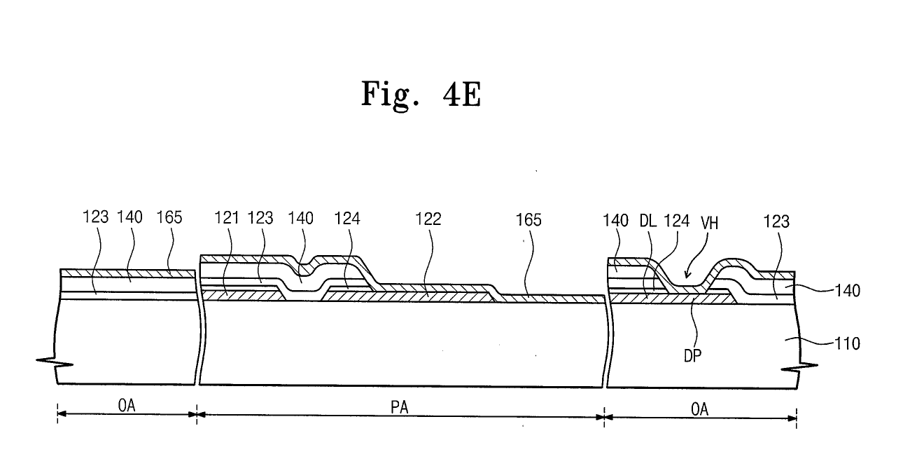

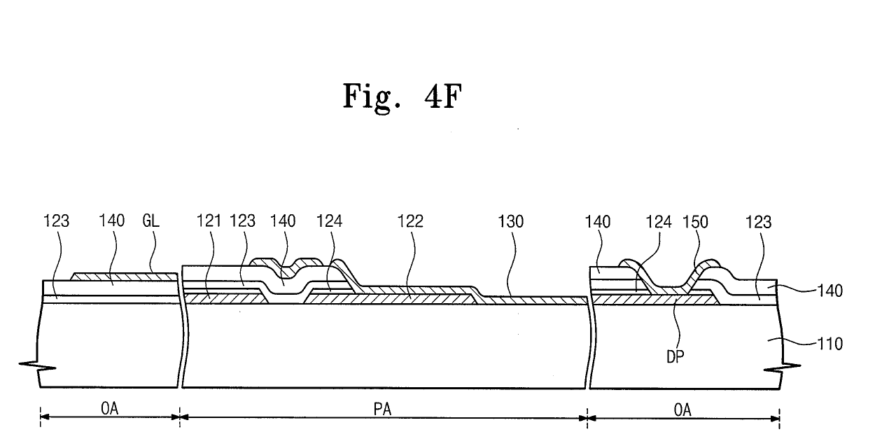

FIGS. 4A to 4F are sectional views illustrating a fabricating method of the display apparatus shown in FIG. 1.

Referring to FIGS. 4A and 4B, a first metal layer 160 is formed on the first base substrate 110, and an n⁺ amorphous silicon layer 170 is formed on the first metal layer 160.

A photoresist layer (not shown) is formed on the n⁺ amorphous silicon layer 170, and then is patterned through a photolithography etching process to form a photoresist layer pattern. The n⁺ amorphous silicon layer 170 is patterned through a dry etching process using the photoresist layer pattern as an etching mask, so that the ohmic contact layer 124 is formed. Next, the first metal layer 160 is patterned through a wet etching process using the photoresist layer pattern as an etching mask, so that the data line DL, the source electrode 121 and the drain electrode 122 are formed, and then the photoresist layer pattern is removed.

Referring to FIGS. 4C and 4D, an amorphous silicon layer 175 and a silicon insulating layer 180 are sequentially formed on the first base substrate 110, and the silicon insulating layer 180 is patterned through a photolithography etching process, so that the first insulating layer 140 is formed. The amorphous silicon layer 175 is patterned through a dry etching process using the first insulating layer 140 as a mask, so that the active layer 123 is formed. In the process of patterning the amorphous silicon layer 175, the ohmic contact layer formed on the drain electrode 122 is partially removed, so that the second end portion of the drain electrode 122 is exposed. In the process of patterning the amorphous silicon layer 175 and the silicon insulating layer 180, the via hole VH is formed.

Referring to FIGS. 4E and 4F, a second metal layer 165 is formed on the first base substrate 110, and is patterned through a photolithography etching process to form the gate line GL, the gate electrode 125, the pixel electrode 130, and the electrode pad 150.

As described above, since the pixel electrode 130 and the electrode pad 150 are formed together with the gate line GL and the gate electrode 125, the number of photolithography etching processes is reduced. Consequently, the number of masks is reduced, so that productivity may be improved and manufacturing cost may be saved.

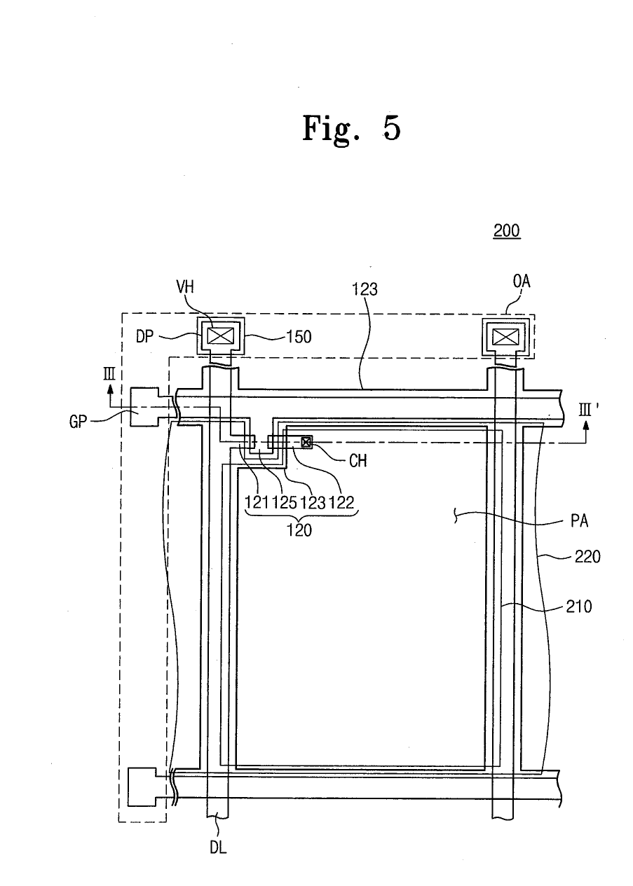

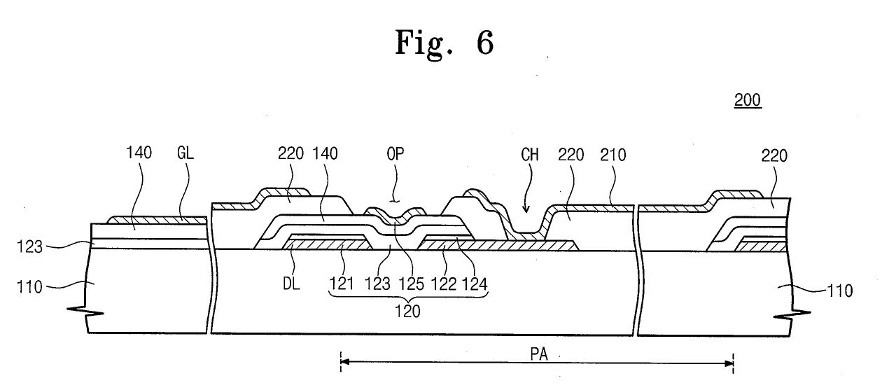

FIG. 5 is a plan view illustrating another exemplary embodiment of a display apparatus according to the present invention, and FIG. 6 is a sectional view taken along a line III-III′ shown in FIG. 5.

Referring to FIGS. 5 and 6, the display substrate 200 has the same construction as that of the display substrate 100 shown in FIGS. 1 to 3, except for a pixel electrode 210 and a second insulating layer 220. In the following description of the display substrate 200, the same reference numerals will be assigned to the elements identical to those of the display substrate 100 shown in FIGS. 1 to 3 and detailed description thereof will be omitted.

The display substrate 200 includes a first base substrate 110, a data line DL, a gate line GL, a thin film transistor 120, and a pixel electrode 210.

A plurality of pixel areas PA representing an image and a peripheral area OA surrounding the pixel areas PA are defined on the first base substrate 110. The data line DL is formed on the upper surface of the first base substrate 110 to transmit data signals, and the gate line GL is insulated from the data line DL while crossing the data line DL to transmit gate signals.

The thin film transistor 120 and the pixel electrode 210 are formed in each of the pixel areas PA of the first base substrate 1 10. The thin film transistor 120 includes a source electrode 121, a drain electrode 122, an active layer 123, an ohmic contact layer 124 and a gate electrode 125. The source electrode 121 is electrically connected to the drain electrode 122 to output a pixel voltage corresponding to the image, and is formed on an area excluding an area on which the gate electrode 125 is formed in the pixel areas PA. The pixel electrode 210 includes the same metal as gate electrode 125, and is obtained in the process of forming the gate electrode 125.

The display substrate 200 further includes a first insulating layer 140 insulating the gate line GL and the gate electrode 125 from a conductive layer formed at a lower portion of the gate line GL and the gate electrode 125. The first insulating layer 140 is formed on the active layer 123 to correspond to the active layer 123, and the gate line GL and the gate electrode 125 are formed on the first insulating layer 140.

The display substrate 200 further includes a second insulating layer 220 formed on the first base substrate 110 and having organic insulating material. Pre determined portions of the second insulating layer 220 are removed at the gate line GL and the peripheral area OA, and the second insulating layer 220 is partially removed at the upper portion of the first insulating layer 140, thereby forming an opening OP exposing the first insulating layer 140. The gate electrode 125 is formed on the first insulating layer 140 exposed through the opening OP.

The second insulating layer 220 is formed on the upper surface of the first insulating layer 140 at the upper portion of the data line DL, and the pixel electrode 210 is formed on the upper surface of the second insulating layer 220. In plan view, the pixel electrode 210 partially overlaps the data line DL, and the second insulating layer 220 is interposed between the pixel electrode 210 and the data line DL on an overlapped area of the pixel electrode 210 and the data line DL, so that parasitic capacitance is avoided between pixel electrode 210 and data line DL.

The second insulating layer 220 is partially removed at the upper surface of the drain electrode 122 to form a contact hole CH therethrough. The pixel electrode 210 is electrically connected to the pixel electrode 210 through the contact hole CH.

The process of fabricating the display substrate 200 will be described in detail with reference to the accompanying drawings.

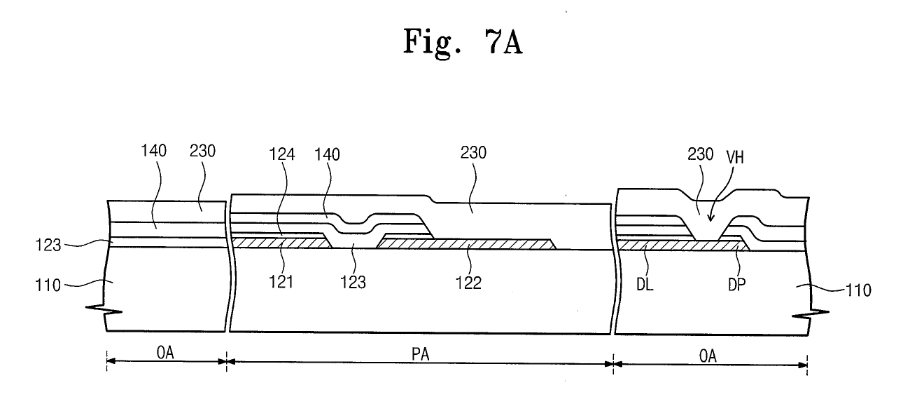

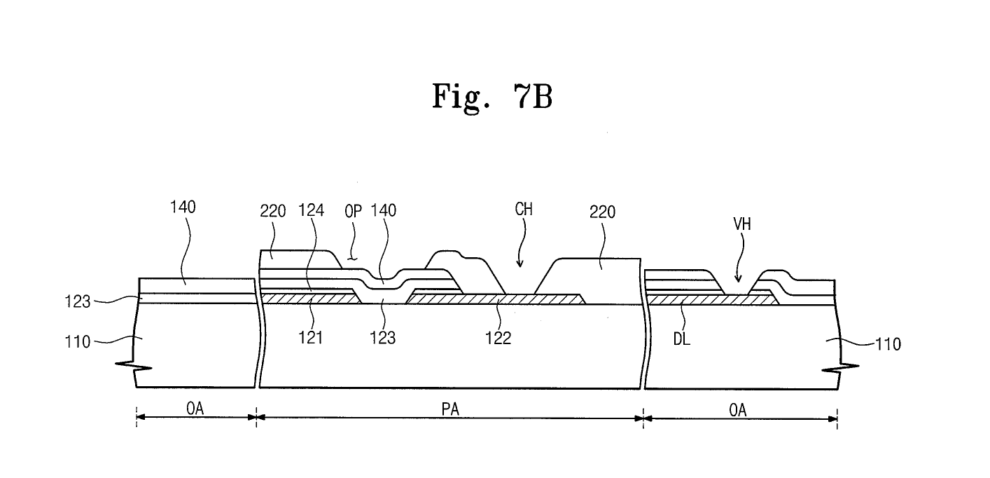

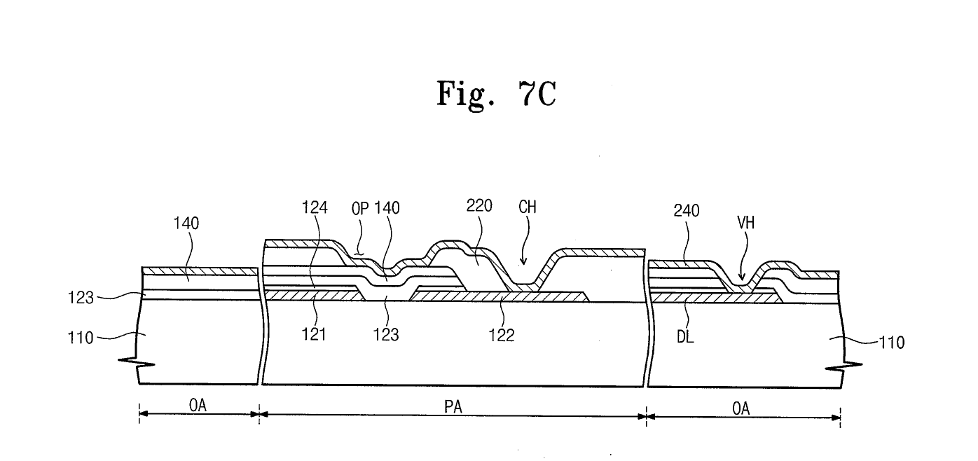

FIGS. 7A to 7C are sectional views illustrating a fabricating method of the display apparatus shown in FIG. 6.

Referring to FIGS. 7A and 7B, the data line DL, the source electrode 121, the drain electrode 122, the active layer 123, the ohmic contact layer 124 and the first insulating layer 140 are formed on the first-base substrate 110. In the present exemplary embodiment, since the data line DL, the source electrode 121, the drain electrode 122, the active layer 123, the ohmic contact layer 124 and first insulating layer 140 are formed through processes equal to those of fabricating the display substrate 100 shown in FIGS. 4A and 4B, detailed descriptions thereof will be omitted.

An organic insulating layer 230 is formed on the first base substrate 110, and is patterned through a photolithography etching process, so that the second insulating layer 220 is formed.

Referring to FIGS. 6 and 7C, a metal layer 240 is formed on the first base substrate 110, and is patterned through a photolithography etching process, so the gate line GL, the gate electrode 125, the pixel electrode 210 and an electrode pad 150 are formed (see FIG. 5).

As described above, in the display substrate 200, the pixel electrode 210 and the electrode pad 150 are formed together with the gate line GL and the gate electrode 125, so that the number of photolithography etching processes are reduced. Consequently, the number of masks is reduced, so that productivity may be improved and manufacturing cost may be saved.

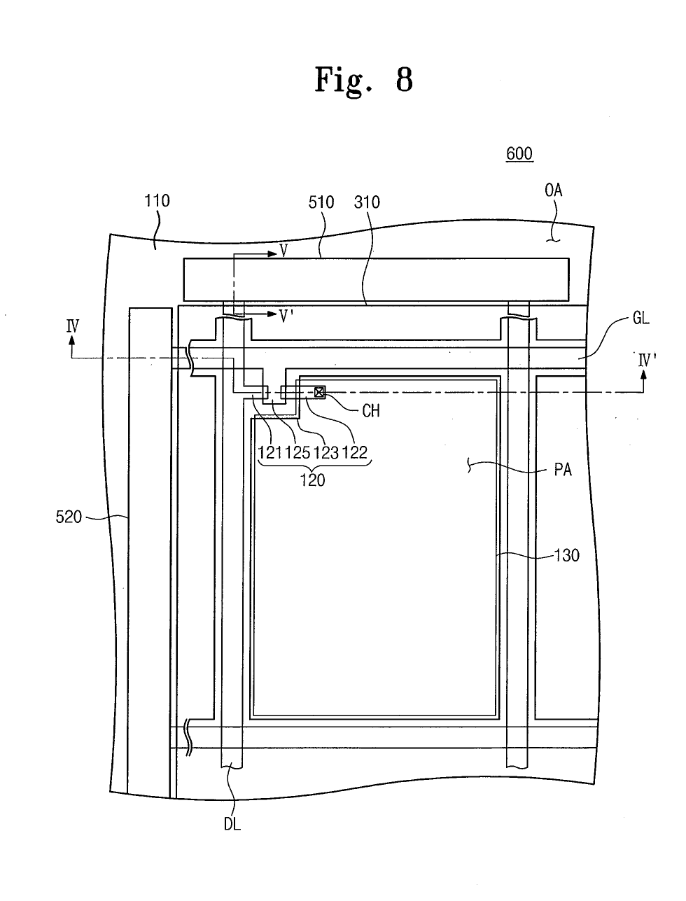

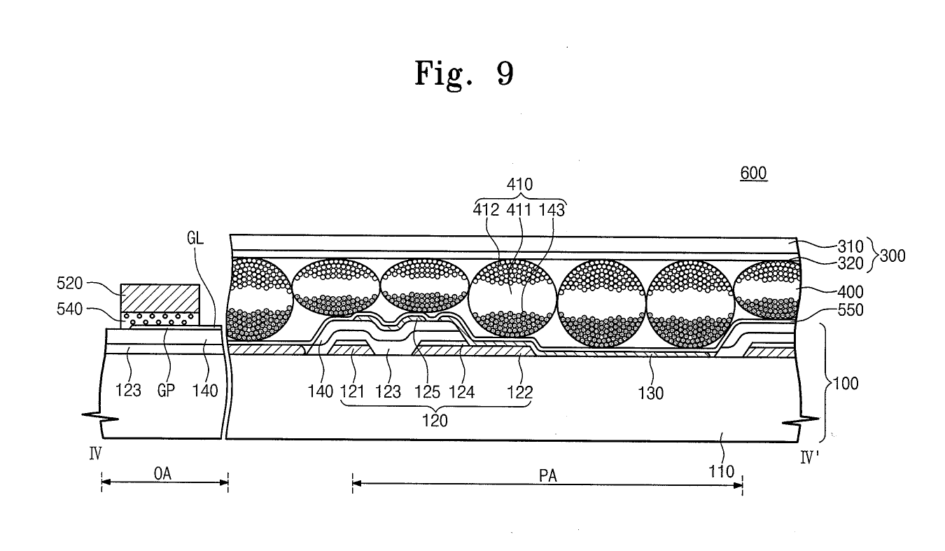

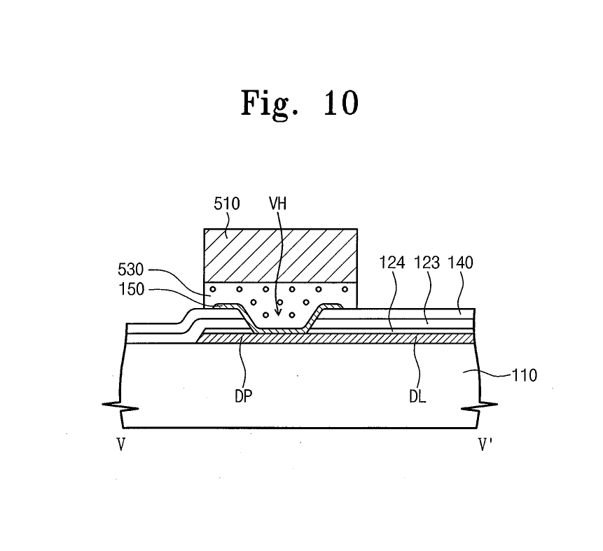

FIG. 8 is a plan view illustrating an exemplary embodiment of an EPD according to the present invention, FIG. 9 is a sectional view taken along a line VI-VI′ shown in FIG. 8, and FIG. 10 is a sectional view taken along a line V-V′ shown in FIG. 8.

Referring to FIGS. 8 and 9, the EPD 600 includes first and second display substrates 100 and 300, a color layer 400, a data driving module 510, a gate driving module 520, a first adhesive member 530 and a second adhesive member 540.

In the present exemplary embodiment, since the first display substrate 100 has the same construction as that of the display substrate 100 shown in FIGS. 1 to 3, the same reference numerals will be assigned to the same elements and detailed description thereof will be omitted. In one embodiment of the present invention, the first display substrate 100 has the same construction as that of the display substrate 100 shown in FIGS. 1 to 3. However, the first display substrate 100 may also have the same construction as that of the display substrate 200 shown in FIGS. 5 and 6.

The second display substrate 300 is mounted on the first display substrate 100 and is faces the first display substrate 100. The second display substrate 300 includes a second base substrate 310 and a common electrode 320. The second base substrate 310 includes a transparent resin material such as Polyethylene Terephthalate (PET). The common electrode 320 is formed on the second base substrate 310 to output a common voltage, and includes a transparent conductive material such as Indium Zinc Oxide (IZO) or Indium Tin Oxide (ITO).

The color layer 400 is interposed between the display substrate 100 and the second display substrate 300. The color layer 400 includes a plurality of microcapsules 410 having a spherical shape, each having a diameter similar to that of a human hair. The micro capsules 410 include a dispersion medium 411 having transparent insulating liquid and a plurality of first and second pigment particles 412 and 413 dispersed in the dispersion medium 411. Each of the first and second pigment particles 412 and 413 is electrified to exhibit a polarity and has a predetermined color. That is, the first pigment particles 412 have polarity and color different from those of the second pigment particles 413.

The first pigment particles 412 are electrified with a positive polarity and have a white color due to a material such as TiO₂. The second pigment particles 413 are electrified with a negative polarity and have a black color due to carbon powder such as carbon black. The first and second pigment particles 412 and 413 have different positions depending on the electric field formed between the first display substrate 100 and the second display substrate 300.

As a negative potential is formed between the first display substrate 100 and the second display substrate 300, the second pigment particles move toward the first display substrate 100 and the first pigment particles move toward the second display substrate 300, so that a white color is displayed. However, as a positive potential is formed between the first display substrate 100 and the second display substrate 300, the first pigment particles move toward the first display substrate 100 and the second pigment particles move toward the second display substrate 300, so that a black color is displayed. Since the potential is formed between the first display substrate 100 and the second display substrate 300 according to the pixel areas PA, the first and second pigment particles have positions set according to the pixel areas PA.

In the present exemplary embodiment, the first pigment particles 412 have a white color, and the second pigment particles 413 have a black color. However, the respective first and second pigment particles 412 and 413 have at least one color of a red, a green, a blue, a cyan, a magenta and a yellow color.

The EPD 600 further includes a third adhesive member 550 bonding the color layer 400 to the first display substrate 100. The third adhesive member 550 is interposed between the color layer 400 and the first display substrate 100 to bond them. As an example of the present embodiment, the color layer 400 is integrally formed with the second display substrate 300, so that the color layer 400 and the second display substrate 300 may also be fabricated as one film.

Referring to FIGS. 8 and 10, the data driving module 510 is mounted on the peripheral area OA of the first display substrate 100. The data driving module 510 is mounted on the electrode pad 150 of the first display substrate 100 to output data signals. The electrode pad 150 is electrically connected to the data pad DP of the data line DL to provide the data pad DP with the data signals output from the electrode pad 150. The first adhesive member 530 is interposed between the electrode pad 150 and the data driving module 510. The first adhesive member 530 includes anisotropic conductive particles to electrically connect the data driving module 510 to the electrode pad 150, and to fix the data driving module 510 to the first display substrate 100.

Referring to FIGS. 8 and 10, the gate driving module 520 is mounted on the peripheral area OA of the first display substrate 100. The gate driving module 520 is mounted on the gate pad GP of the first display substrate 100 to output gate signals. The second adhesive member 540 is interposed between the gate driving module 520 and the gate pad GP. The second adhesive member 540 includes anisotropic conductive particles to electrically connect the gate driving module 520 to the gate pad GP, and to fix the gate driving module 520 to the first display substrate 100.

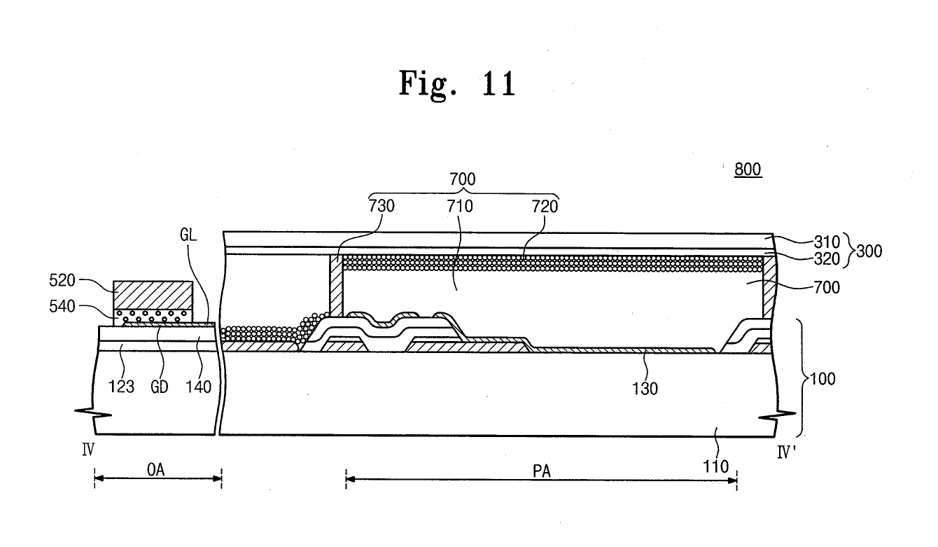

FIG. 11 is a sectional view illustrating another exemplary embodiment of an EPD according to the present invention.

Referring to FIG. 11, the EPD 800 has the same construction as that of the EPD 600 shown in FIGS. 8 to 10, except for a color layer 700. In the following description of the EPD 800, the same reference numerals will be assigned to the elements identical to those of the EPD 600 shown in FIGS. 8 to 10 and detailed description thereof will be omitted.

The EPD 800 includes a first display substrate 100, a second display substrate 300 facing the first display substrate 100, the color layer 700 interposed between the first display substrate 100 and the second display substrate 300, a data driving module 510 (see FIG. 8) providing data signals, a gate driving module 520 providing gate signals, a first adhesive member 530 (see FIG. 10) fixing the data driving module 510 to the first display substrate 100, and a second adhesive member 540 fixing the gate driving module 520 to the first display substrate 100. In the present exemplary embodiment, since the first display substrate 100 of the EPD 800 has the same construction as that of the display substrate 100 shown in FIGS. 1 to 3. However, the first display substrate 100 may also have the same construction as that of the display substrate 200 shown in FIGS. 5 and 6.

The color layer 700 displays predetermined colors depending on electric field formed between the first display substrate 100 and the second display substrate 300. That is, the color layer 700 includes a fluid layer 710 having insulating liquid with predetermined colors and a plurality of pigment particles 720 dispersed in the fluid layer 710. Each pigment particle 720 has a color different from that of the fluid layer 710, is electrified with a negative polarity or a positive polarity, and has different positions depending on electric field formed between the first display substrate 100 and the second display substrate 300.

For example, as the pigment particles 720 are electrified with the negative polarity and the negative potential is formed between the first display substrate 100 and the second display substrate 300, the pigment particles 720 move toward the first display substrate 100, so that a color of the fluid layer 710 is displayed. However, as the positive potential is formed between the first display substrate 100 and the second display substrate 300, the pigment particles move toward the second display substrate 300, so that a color of the pigment particles is displayed. Since the potential is formed between the first display substrate 100 and the second display substrate 300 according to the pixel areas PA, the pigment particles have positions set according to the pixel areas PA.

The color layer 700 further includes a partition 730 surrounding the pixel areas PA. The partition 730 forms a receiving space that receives the fluid layer 710 and the pigment particles 720 according to the pixel areas PA such that the fluid layer 710 and the pigment particles 720 are encapsulated between the first display substrate 100 and the second display substrate 300, thereby preventing colors from being mixed in two adjacent pixel areas.

According to the above-described embodiments, in the first display substrate, the gate electrode is formed on the active layer, and the pixel electrode is formed with the material the same as that of the gate electrode. Consequently, the number of process steps and the number of masks are reduced, so that the productivity may be improved and the manufacturing cost may be saved.

Although the exemplary embodiments of the present invention have been described, it is understood that the present invention should not be limited to these exemplary embodiments but various changes and modifications can be made by one ordinary skilled in the art within the spirit and scope of the present invention as hereinafter claimed.

What is claimed is:

1. A display substrate comprising:
a base substrate on which pixel areas representing an image are defined;
a thin film transistor formed in the pixel areas to switch a pixel voltage corresponding to an image; and
a pixel electrode formed in the pixel areas and electrically connected to the thin film transistor to output the pixel voltage; the thin film transistor comprising:
a source electrode formed on the base substrate;
a drain electrode formed on the layer on which the source electrode is formed so as to be electrically connected to the pixel electrode;
an active layer covering the source electrode and the drain electrode; and
a gate electrode formed on the active layer together with the pixel electrode and comprising a same material as that of the pixel electrode.

2. The display substrate of claim 1, further comprising a first insulating layer interposed between the active layer and the gate electrode and formed corresponding to the active layer.

3. The display substrate of claim 2, wherein the active layer and the first insulating layer are partially removed at an upper surface of the drain electrode to expose the drain electrode, and the pixel electrode makes contact with an exposed portion of the drain electrode.

4. The display substrate of claim 2, further comprising:
a data line formed on the base substrate and electrically connected to the source electrode to transmit data signals; and
a gate line formed on the first insulating layer and insulated from the data line, in which the gate line is electrically connected to the gate electrode to transmit gate signals.

5. The display substrate of claim 4, wherein the pixel electrode is spaced apart from the gate line and the data line when viewed in plan view.

6. The display substrate of claim 4, further comprising a second insulating layer formed on the base substrate including the first insulating layer, and removed at an area corresponding to the gate electrode.

7. The display substrate of claim 6, wherein the second insulating layer is partially removed such that a contact hole exposing the drain electrode and an opening exposing the first insulating layer are formed, the pixel electrode is formed on the second insulating layer to be electrically connected to the drain electrode through the contact hole, and the gate electrode is formed on the first insulating layer exposed through the opening.

8. The display substrate of claim 7, wherein the pixel electrode partially overlaps the gate line and the data line when viewed in a plan view.

9. The display substrate of claim 1, wherein the pixel electrode comprises an opaque metallic material.

10. An electrophoretic display comprising:
a first display substrate;
a second display substrate facing the first display substrate; and
a color layer of charged pigment particles interposed between the first display substrate and the second display substrate for representing an image,
wherein the first display substrate comprises:
a first base substrate on which pixel areas representing an image are defined;
a thin film transistor formed in the pixel areas to switch a pixel voltage corresponding to an image; and
a pixel electrode formed in the pixel areas and electrically connected to the thin film transistor to output the pixel voltage; wherein the thin film transistor comprises:
a source electrode formed on the first base substrate;
a drain electrode formed on a layer, on which the source electrode is formed, and electrically connected to the pixel electrode;
an active layer covering the source electrode and the drain electrode; and
a gate electrode obtained on the active layer, in which the gate electrode comprises the same material as that of the pixel electrode.

11. The electrophoretic display of claim 10, wherein the first display substrate further comprises:
a first insulating layer interposed between the active layer and the gate electrode and formed corresponding to the active layer;
a data line formed on the first base substrate and electrically connected to the source electrode to transmit data signals; and
a gate line formed on the first insulating layer and insulated from the data line while crossing the data line, in which the gate line is electrically connected to the gate electrode to transmit gate signals and defines the pixel areas together with the data line.

12. The electrophoretic display of claim 10, wherein the color layer comprises a plurality of microcapsules formed by encapsulating the pigment particles.

13. The electrophoretic display of claim 12, further comprising an adhesive member interposed between the color layer and the first display substrate to bond the color layer to the first display substrate.

14. The electrophoretic display of claim 10, wherein the color layer comprises a fluid layer having predetermined colors and including the pigment particles dispersed therein.

15. The electrophoretic display of claim 14, further comprising a partition interposed between the first display substrate and the second display substrate to surround the pixel areas, and to seal the fluid layer between the first display substrate and the second display substrate.

16. A method of fabricating a display substrate, the method comprising:
forming a source electrode and a drain electrode in pixel areas of a base substrate;
forming an active layer covering the source electrode and the drain electrode in the pixel areas; and
forming a gate electrode on the active layer and substantially simultaneously forming a pixel electrode electrically connected to the drain electrode.

17. The method of claim 16, wherein the gate electrode and the pixel electrode are formed by:
forming a gate metal layer on the base substrate; and
patterning the gate metal layer to form the active layer and the pixel electrode.

18. The method of claim 16, further comprising forming a first insulating layer before the forming of the gate electrode and the pixel electrode, in which the first insulating layer is patterned together with the active layer.

19. The method of claim 18, further comprising forming a second insulating layer before the forming of the gate electrode and the pixel electrode, in which the second insulating layer is partially removed at an upper surface of the first insulating layer to form an opening therethrough, the gate electrode is formed on the first insulating layer exposed through the opening, and the pixel electrode is formed on the second insulating layer.

20. The method of claim 16, further comprising forming an ohmic contact layer on the source electrode and the drain electrode before the forming of the active layer.
